(19) United States
(12) Patent Application Publication
(10) Pub. No.: US 2018/0233661 A1
(43) Pub. Date: Aug. 16, 2018

(54) DEVICE ALIGNMENT MARK USING A PLANARIZATION PROCESS

(71) Applicant: GLOBALFOUNDRIES Singapore Pte. Ltd., Singapore (SG)

(72) Inventors: Benfu LIN, Singapore (SG); Kah Wee GAN, Singapore (SG); Chim Seng SEET, Singapore (SG)

(21) Appl. No.: 15/432,933

(22) Filed: Feb. 15, 2017

(51) Int. Cl. H01L 43/12; H01L 43/02; H01L 43/08; H01L 43/10; H01L 27/22

(52) U.S. Cl. CPC H01L 43/12; H01L 43/02; H01L 27/228; H01L 43/10; H01L 43/08

(57) ABSTRACT

Device and methods of forming a device are disclosed. The method includes providing a substrate and forming a dielectric layer over the substrate. An alignment mark opening which extends through the dielectric layer is formed. A conductive layer is deposited over the dielectric layer. A planarization process is performed to remove excess conductive material on the dielectric layer and recess a top surface of the conductive material in the alignment mark opening with respect to the dielectric layer, forming an alignment mark of the device. A first electrode layer may be formed over the dielectric layer, wherein a topography of the dielectric layer and the alignment mark in the dielectric layer is transferred to the first electrode layer.

### BACKGROUND

Memory cells, for example, include magnetic tunnel junction (MTJ) elements which uses magnetic polarization to store information. The memory cells, for example, include MTJ stack layers having a plurality of magnetic layers which are generally connected to interconnects in the interlevel dielectric (ILD) layer. The MTJ stack layers may be patterned to be aligned with the underlying interconnects. However, conventional processes for forming the MTJ stack layers may result in reliability issues in the memory device, such as out diffusion of material from the via plug beneath the bottom electrode of the MTJ stack layers due to insufficient bottom electrode coverage on uneven via plug surface.

Accordingly, it is desirable to provide improved, reliable and cost effective techniques for aligning the various MTJ stack layers with the underlying interconnect structure.

### SUMMARY

Embodiments of the present disclosure generally relate to semiconductor device and methods for forming a semiconductor device. In one aspect, a method of forming an alignment mark in a device is disclosed. The method includes providing a substrate and forming a dielectric layer over the substrate. An alignment mark opening which extends through the dielectric layer is formed. A conductive layer is deposited over the dielectric layer. A planarization process is performed to remove excess conductive material on the dielectric layer and recess a top surface of the conductive material in the alignment mark opening with respect to the dielectric layer, forming an alignment mark of the device. A first electrode layer may be formed over the dielectric layer, wherein a topography of the dielectric layer and the alignment mark in the dielectric layer is transferred to the first electrode layer.

In another aspect, a wafer is disclosed. The wafer includes a wafer substrate and a dielectric layer disposed over the substrate. An alignment mark is disposed in the dielectric layer, wherein the alignment mark is recessed with a step height from a top surface of the dielectric layer.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the disclosure. In the following description, various embodiments of the present disclosure are described with reference to the following drawings, in which:

FIG. 1 shows a simplified plan view of a portion of an embodiment of a semiconductor wafer;

FIG. 2a shows a cross-sectional view of an embodiment of a device;

FIG. 2b shows a cross-sectional view of an embodiment of a device in greater detail;

FIGS. 3a-3e show simplified cross-sectional views of an embodiment of a process for forming an alignment mark in a device; and

FIGS. 4a-4c show another embodiment of a process for forming an alignment mark in a device.

### DETAILED DESCRIPTION

Embodiments of the present disclosure generally relate to semiconductor device and methods for forming a semiconductor device. The embodiments generally relate to methods for forming alignment mark to facilitate patterning of memory stack layers in a memory device. More particularly, a planarization process such as chemical mechanical polishing (CMP) is employed for forming the alignment mark. In one embodiment, a CMP process is used to planarize the conductive material directly below the memory stack layers prior to depositing a first electrode of the memory stack layers. The planarization forms a recessed surface which serves as the alignment mark. For example, the conductive material is recessed with respect to a dielectric layer of the device. The memory device, for example, may be a magnetic random access memory (MRAM) device. The memory device includes a memory cell having a magnetic tunnel junction (MTJ) element. Other suitable types of memory devices may also be useful. Such memory device can be incorporated into standalone memory devices including, but not limited to, USB or other types of portable storage units, or ICs, such as microcontrollers or system on chips (SoCs). The devices or ICs may be incorporated into or used with, for example, consumer electronic products, or relate to other types of devices.

After processing of the wafer is completed, the wafer is diced along the scribe lane or dicing channel to produce individual dies. The dies may be processed to include package bumps. For example, wafer level packaging may be performed prior to dicing the wafer. The dies may be packaged and mounted onto an external component, such as a package substrate or a circuit board.

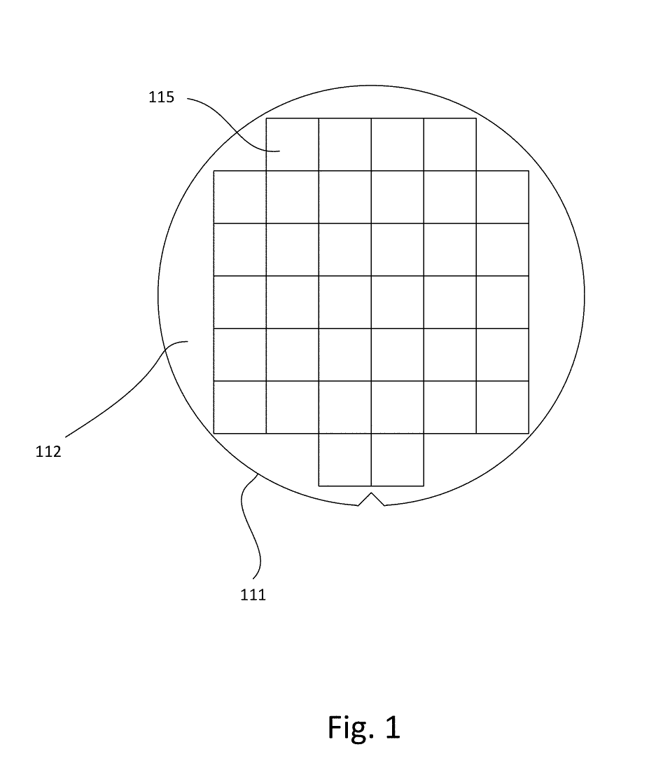

FIG. 1 shows a simplified plan view of a portion of an embodiment of a semiconductor wafer 111. The semiconductor wafer, for example, may be a silicon wafer. Other types of wafers are also useful. For example, the wafer may be a p-type or n-type doped wafer. The wafer includes a surface 112 on which a plurality of devices 115 is formed. The plurality of devices may be formed on the wafer in parallel. The devices, for example, are arranged in rows along a first (x) direction and columns along a second (y) direction. The devices are singulated by dicing the wafer along the scribe lanes or dicing channels.

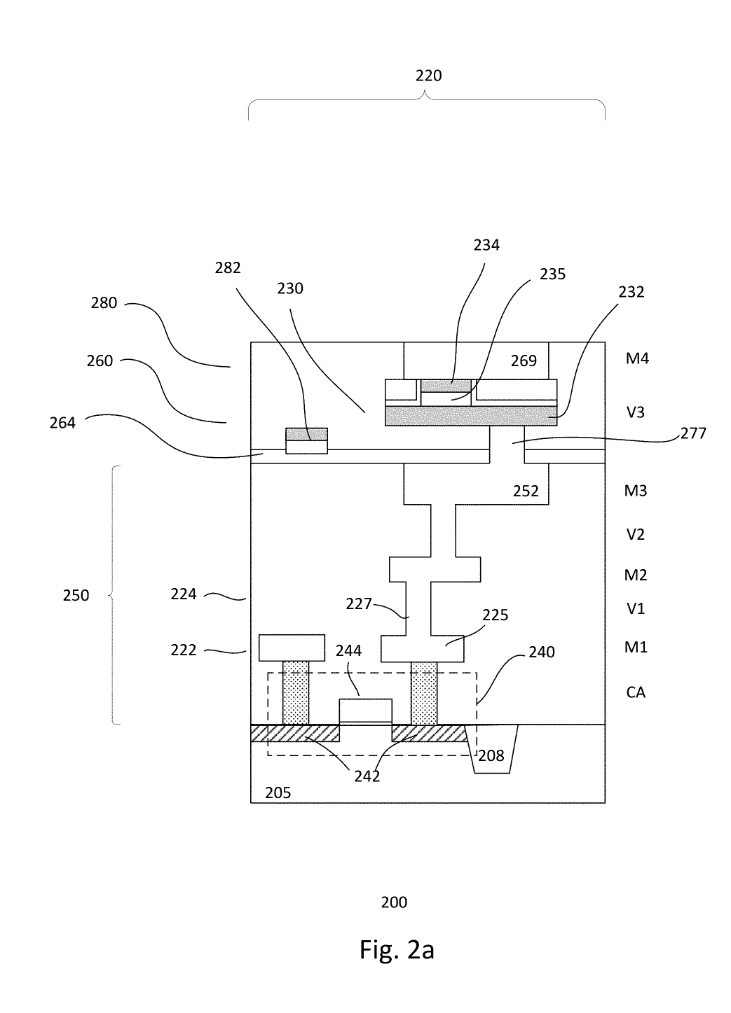

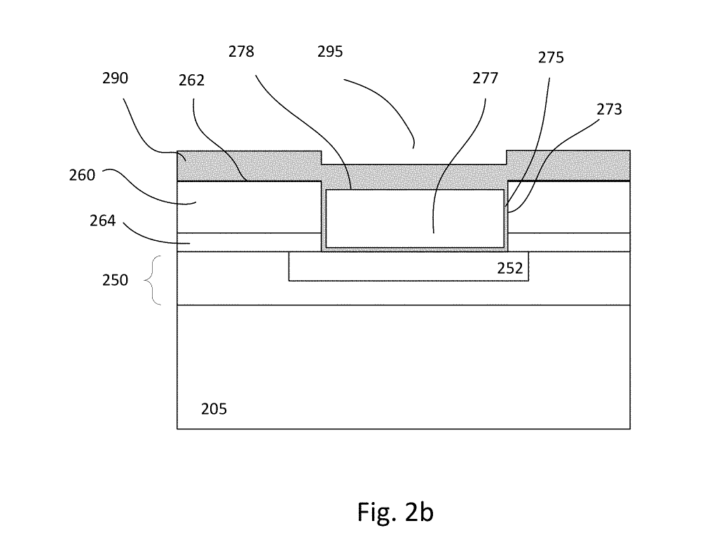

FIG. 2a shows a cross-sectional view of an embodiment of a device 200. A memory cell region 220 of the device is illustrated. The cross-sectional view, for example is along a second or bitline direction of the device. The device, as shown, includes a memory cell 230 and cell selector unit or transistor 240. The memory cell, for example, may be a non-volatile memory (NVM) cell. The memory cell, in one embodiment, is a magnetoresistive NVM cell, such as a spin transfer torque magnetic random access memory (STT-MRAM) cell. Other suitable type of memory cells may also be useful.

The memory cell is disposed on a substrate 205. For example, the memory cell is disposed in the memory cell region 220 of the substrate. The memory cell region may be part of an array region. For example, the array region may include a plurality of memory cell regions. The substrate may include other types of device regions (not shown), such as high voltage (HV), low voltage (LV) and intermediate voltage (IV) device regions. Other types of regions may also be provided.

The substrate, for example, is a semiconductor substrate, such as a silicon substrate. For example, the substrate may be a lightly doped p-type substrate. Providing an intrinsic or other types of doped substrates, such as silicon-germanium (SiGe), germanium (Ge), gallium-arsenic (GaAs) or any other suitable semiconductor materials, may also be useful. In some embodiments, the substrate may be a crystalline-on-insulator (COI) substrate. A COI substrate includes a surface crystalline layer separated from a crystalline bulk by an insulator layer. The insulator layer, for example, may be formed of a dielectric insulating material. The insulator layer, for example, is formed from silicon oxide, which provides a buried oxide (BOX) layer. Other types of dielectric insulating materials may also be useful. The COI substrate, for example, is a silicon-on-insulator (SOI) substrate. For example, the surface and bulk crystalline layers are single crystalline silicon. Other types of COI substrates may also be useful. It is understood that the surface and bulk layers need not be formed of the same material. The substrate may be a part of the wafer 111 as described in FIG. 1 which is processed in parallel to form a plurality of devices.

The substrate includes first and second surfaces. The first surface may be the top surface on which an IC is mounted while the second surface is the bottom surface which is mounted onto, for example, an external component, such as a package substrate or a circuit board. In one embodiment, n-type and p-type devices or transistors may be formed in the memory cell region as well as other regions on the substrate. The p-type and n-type devices, for example, may be formed on the substrate using front end of line (FEOL) processing. In some embodiments, a p-type and n-type device forms a complementary MOS (CMOS) device. The FEOL processing, for example, includes forming isolation regions, various device and isolation wells, transistor gates and transistor source/drain (S/D) regions and contact or diffusion regions serving as substrate or well taps. Forming other components with the FEOL process may also be useful.

As shown, a memory cell region 220 may be isolated by an isolation region 208, such as a shallow trench isolation (STI) region. For example, the memory cell region is for a memory cell. Isolation regions may be provided to isolate columns of memory cells. Other configurations of isolation regions may also be useful. The cell region may include a cell device well (not shown). The cell device well, for example, serves as a body well for a cell select transistor 240 of the memory cell 230. The cell device well may be doped with second polarity type dopants for first polarity type cell select transistor. The device well may be lightly or intermediately doped with second polarity type dopants. In some cases, a cell device isolation well (not shown) may be provided, encompassing the cell device well. The isolation well may have a dopant type which has the opposite polarity to that of the cell device well. For example, the isolation well may include first polarity type dopants. The isolation well serves to isolate the cell device well from the substrate. Well biases may be provided to bias the wells.

The cell device well may be a common well for the cell regions in the array region. For example the cell device well may be an array well. The cell device isolation well may serve as the array isolation well. Other configurations of device and isolation wells may also be useful. Other device regions of the device may also include device and/or device isolation wells.

In some embodiments, the cell selector unit includes a selector for selecting the memory cell 230. The selector, for example, may be a select transistor. In one embodiment, the select transistor is a metal oxide semiconductor (MOS) transistor. The transistor, as shown, includes first and second source/drain (S/D) regions 242 formed in the substrate 205 and a gate 244 disposed on the substrate between the S/D regions. The S/D regions, for example, are heavily doped regions with first polarity type dopants, defining the first type select transistor. For example, in the case of a n-type transistor, the S/D regions are n-type heavily doped regions. Other types of transistors or selectors may also be useful. As for the gate 244, it includes a gate electrode over a gate dielectric. The gate electrode may be polysilicon while the gate dielectric may be silicon oxide. Other types of gate electrode and gate dielectric materials may also be useful. A gate, for example, may be a gate conductor along a first or wordline direction. The gate conductor forms a common gate for a row of memory cells.

Interconnects may be disposed in interlevel dielectric (ILD) layers on the substrate. For example, the interconnects may be formed using back end of line (BEOL) processing. The interconnects connect the various components of the IC to perform the desired functions. An ILD level includes a metal level 222 and a contact level 224. Generally, the metal level includes conductors or metal lines 225 while the contact level includes via contacts 227. The conductors and contacts may be formed of a metal, such as copper, copper alloy, aluminum, tungsten or a combination thereof. Other suitable types of metal, alloys or conductive materials may also be useful. In some cases, the conductors and contacts may be formed of the same material. For example, in upper metal levels, the conductors and contacts may be formed by dual damascene processes, forming conductors and contacts of the same material. In some cases, the conductors and contacts may have different materials. For example, in the case where the contacts and conductors are formed by single damascene processes, the materials of the conductors and contacts may be different. Other techniques, such as reactive ion etch (RIE) may also be employed to form metal lines.

As illustrated, a device may include a plurality of ILD layers or levels. For example, x number of ILD levels may be provided. For example, the device includes four ILD levels (x=4). Other number of ILD levels may also be useful. The number of ILD levels may depend on, for example, design requirements or the logic process involved. A metal level of an ILD level may be referred to as Mᵢ, where i is from 1 to x and is the i^{th} ILD level of x ILD levels. A contact level of an ILD level may be referred to as Vᵢ₋₁, where i is the i^{h} ILD level of x ILD levels.

Using the BEOL process, for example, a first dielectric layer 250 is disposed over the transistors and other components formed in the FEOL process. The first dielectric layer 250 may include a plurality of ILD levels. For example, a first ILD layer includes a pre-metal dielectric layer or first contact (CA) layer disposed on the substrate. The CA layer may be silicon oxide. For example, the CA layer may be silicon oxide formed by chemical vapor deposition (CVD). Contacts are formed in the CA layer. The contacts may be formed by a single damascene process. Via openings are formed in the CA layer using mask and etch techniques. For example, a patterned resist mask with openings corresponding to the vias is formed over the dielectric layer. An anisotropic etch, such as RIE, is performed to form the vias, exposing contact regions below, such as S/D regions and gates. A conductive layer, such as tungsten is deposited on the substrate, filling the openings. The conductive layer may be formed by sputtering or chemical vapor deposition (CVD). Other techniques may also be useful. A planarization process, such as chemical mechanical polishing (CMP), is performed to remove excess conductive material, leaving contact plugs in the CA layer.

A first metal level M1 of the first ILD layer may be disposed on the CA layer. The first metal level M1 of the first ILD layer, for example, is a silicon oxide layer. Other types of dielectric layers may also be useful. The dielectric layer may be formed by CVD. Other techniques for forming the first ILD layer may also be useful.

Conductive lines 225 are formed in the M1 level dielectric layer. The conductive lines may be formed by a damascene technique. For example, the dielectric layer may be etched to form trenches or openings using, for example, mask and etch techniques. A conductive layer is formed on the substrate, filling the openings. For example, a copper or copper alloy layer may be formed to fill the openings. The conductive material may be formed by, for example, plating, such as electro or electroless plating. Other types of conductive layers or forming techniques may also be useful. Excess conductive materials are removed by, for example, CMP, leaving planar surface with the conductive line and M1 level dielectric layer. The first metal level M1 and CA may be referred as a lower ILD level.

Additional ILD layers or upper ILD layers/levels may be disposed on the first ILD layer. For example, as illustrated, the additional levels in the first dielectric layer include ILD levels from 2 to 3, which includes M2 to M3. The number of ILD layers may depend on, for example, design requirements or the logic process involved. The ILD layers may be formed of silicon oxide. Other types of dielectric materials, such as low k, high k or a combination of dielectric materials may also be useful. The ILD layers may be formed by, for example, CVD. Other techniques for forming the ILD layers may also be useful.

The conductors and contacts of the additional ILD layers may be formed by dual damascene techniques. For example, vias and trenches are formed, creating dual damascene structures. The dual damascene structure may be formed by, for example, via first or via last dual damascene techniques. Mask and etch techniques may be employed to form the dual damascene structures. The dual damascene structures are filled with a conductive layer, such as copper or copper alloy. The conductive layer may be formed by, for example, plating techniques. Excess conductive material is removed by, for example, CMP, forming conductors and contacts in an ILD layer.

A dielectric liner (not shown) may be disposed between ILD levels and on the substrate. The dielectric liner, for example, serves as an etch stop layer. The dielectric liner may be formed of a low k dielectric material. For example, the dielectric liner may be nBLOK. Other types of dielectric materials for the dielectric liner may also be useful.

As shown, S/D contacts are disposed in the CA level. The S/D contacts are coupled to the first and second S/D regions of the select transistor. Other S/D contacts to other S/D regions of transistors may also be provided. The CA level may include a gate contact (not shown) coupled to the gate of the select transistor. The gate contact may be disposed in another cross-section of the device. The gate contact is coupled to a wordline (WL) which may be provided by the gate or provided in any suitable metal level. The contacts may be tungsten contacts. Other types of contacts may also be useful. Other S/D and gate contacts for other transistors may also be provided.

As described, metal lines are provided in M1. The metal lines are coupled to the S/D contacts. In one embodiment, a SL is coupled to the second S/D region of the select transistor. As for the first S/D contact, it may be coupled to contact pad or island in M1. The contact pads provide connections to upper ILD levels. The metal lines or pads may be formed of copper or copper alloy. Other types of conductive material may also be useful.

As for the additional ILD levels, for example, from 2 to 3, they include contacts 227 in the via level 224 and contact pads/metal lines 225 in the metal level 222. The contacts and contact pads provide connection from an uppermost metal level of the device to the first S/D region of the select transistor.

In some embodiments, a dielectric liner 264 is disposed above the first dielectric layer 250. The dielectric liner, for example, serves as an etch stop layer. The dielectric liner may be a low k dielectric liner. For example, the dielectric liner may be nBLOK or nitride. Other suitable types of dielectric materials for the dielectric liner may also be useful.

In one embodiment, a second dielectric layer 260 is disposed on the first dielectric layer 250. For example, the second dielectric layer is disposed on the dielectric liner 264. The second dielectric layer, in one embodiment, is TEOS. Any suitable dielectric materials for the second dielectric layer may be useful. In one embodiment, a conductive material 277 is disposed in the second dielectric layer 260 and is coupled to a metal line 252 in the first dielectric layer 250. In one embodiment, a top surface of the conductive material is recessed from a top surface of the second dielectric layer, as will be described in more detail with reference to FIG. 2b. The recessed surface with respect to the dielectric layer serves as the alignment mark for forming a memory cell. The alignment mark, for example, includes a conductive material, such as Cu. Other suitable types of conductive material may also be useful.

The memory cell region 220 accommodates a memory cell 230. As shown, the memory cell 230 is disposed over the second dielectric layer 260 in the cell region 220. In one embodiment, the memory cell is a STT-MRAM cell. Other suitable types of memory cells may also be useful. The memory cell includes a storage unit which is a magnetic memory element, such as a MTJ element.

The memory element includes first and second electrodes 232 and 234. In one embodiment, the first electrode follows the topography of the second dielectric layer and the recessed alignment mark in the second dielectric layer on which the first electrode is disposed. For example, a portion of a top surface of the first electrode which is disposed on the alignment mark is recessed. In other words, the profile of the recessed alignment mark in the second dielectric layer is transferred to a portion of the top surface of the first electrode. The recessed portion of the top surface of the first electrode at a special designed macro serves as an alignment mark to facilitate patterning subsequently formed layers in the device. Providing the alignment mark for forming other subsequent structures in the device may also be useful. The first electrode, for example, may be a bottom electrode while the second electrode may be a top electrode of a MTJ element. Other configurations of electrodes may also be useful. The first electrode 232 of the memory element is connected to the metal line 252 through the conductive material 277.

As described, the alignment mark is formed by the conductive material recessed with respect to a top surface of a dielectric layer such as the second dielectric layer. The conductive material 277 forming the alignment mark, in one embodiment, contacts the metal line 252 disposed in the first dielectric layer underlying the second dielectric layer in which the alignment mark is formed. In other embodiments, the alignment mark may be floating in the dielectric layer. For example, a floating alignment mark 282 in the second dielectric layer does not contact a metal line.

The memory element includes a memory stack 235 disposed in between the first and second electrodes. In one embodiment, the memory stack is disposed over a flat portion of the first electrode. For example, the memory stack is disposed over an ultra-flat portion of the first electrode. For example, a critical underlying flat surface is required for the memory stack. The memory element, for example, may include a bottom-pinned MTJ element or a top-pinned MTJ element. Top and bottom refer to position of layers relative to the substrate surface. It is understood that the memory stack may include any suitable number of layers. For example, the memory stack generally includes a magnetically fixed (pinned) layer, one or more tunneling barrier layers and a magnetically free layer. The fixed layer includes a magnetic layer and a pinning layer. The pinning layer, for example, pins the magnetization direction of the magnetic layer, forming a pinned layer. The free layer may be CoFeB, the tunneling barrier layer may be MgO or Al₂O₃, and the magnetic layer may be CoFeB/Ru/CoFeB. As for the pinning layer, it may be PtMn or IrMn. The top and bottom electrodes may be Ti, TiN, Ta, TaN or other suitable metals used for memory elements. Other suitable configurations or materials of the memory element may also be useful.

A third dielectric layer 280 is disposed over the second dielectric layer 260, covering the memory cell. The third dielectric layer, for example, corresponds to an upper ILD level 4. The third dielectric layer, for example, is a dielectric stack having one or more dielectric layers. For instance, the third dielectric layer 280 may include any suitable number of dielectric layers. The third dielectric layer may be formed of TEOS or low K/SOG material. Other suitable configurations and materials for the dielectric layer may also be useful.

The third dielectric layer 280, for example, includes a metal line 269. The metal line 269, for example, is disposed on the memory cell. For example, the metal line 269 may be disposed in metal level M4. The metal line 269, for example, may serve as a bitline (BL). Providing the bitline at other metal level may also be useful. Although one metal line 269 is shown, it is understood that there could be other suitable number of metal lines in the same metal level.

In some embodiments, additional dielectric liner and dielectric layers may optionally be disposed over the upper ILD level 4. A pad level (not shown) may be disposed over the uppermost ILD level. For example, a pad dielectric level is disposed over Mx. In the case where the device includes 4 metal levels, the pad level is disposed over M4. The pad level includes a pad dielectric layer. The pad dielectric layer, for example, may be a silicon oxide layer. Other types of pad dielectric layer may also be useful. A pad interconnect (not shown) having a pad via contact and a contact pad may be disposed in the pad level. The pad interconnect, for example, electrically connects to an interconnect in the uppermost ILD level. The pad interconnect, for example, includes an aluminum pad interconnect. Other suitable conductive material may also be useful. A passivation layer may be disposed over the pad dielectric layer. An opening in the passivation layer exposes the contact pad for subsequent wire bonding to provide external connections to the device.

In the example, the memory cell is formed in between adjacent upper ILD levels, such as upper ILD level 3 to 4. It is understood that the memory cell may be disposed in between any suitable adjacent ILD levels.

FIG. 2b shows a portion of an embodiment of the device 200 with an alignment mark in greater detail. The device may be at an intermediate stage, for example, prior to forming the memory cell. As illustrated, the device includes the first dielectric layer 250 disposed on the substrate 205. In one embodiment, the first dielectric layer includes one or more ILD layers. The first dielectric layer, for example, may include any level of an ILD layer. For example, the uppermost layer of the first dielectric layer corresponds to ILD level 3. The ILD level 3, for example, includes a via level and a metal level. The ILD level 3, for example, includes via level V2 and metal level M3. One or more via contacts (not shown) may be disposed in V2 in the memory cell region. The first dielectric layer, in one embodiment, may be formed of silicon oxide. Providing other material or combination of layers of different materials for the first dielectric layer may also be useful.

As shown, a metal line 252 is disposed in the metal level (e.g., M3) of the first dielectric layer 250. The metal line 252, for example, may be coupled to a subsequently formed memory cell. The metal line 252, for example, may serve as a bitline (BL) or may be used for connection purpose. Although one metal line 252 is shown, it is understood that there could be other suitable number of metal lines in the same metal level. The metal line 252 includes a conductive material. The conductive material, for example, includes copper (Cu). Other suitable types of conductive material may also be useful.

In one embodiment, a dielectric liner 264 is disposed above the first dielectric layer 250. The dielectric liner, for example, serves as an etch stop layer. The dielectric liner may be a low k dielectric liner. For example, the dielectric liner may be nBLOK or nitride. Other suitable types of dielectric materials for the dielectric liner may also be useful.

A second dielectric layer 260 is disposed on the first dielectric layer 250. For example, the second dielectric layer is disposed on the dielectric liner 264. The second dielectric layer, in one embodiment, is TEOS. The second dielectric layer, for example, may have a thickness of 1000 Å. Any suitable dielectric materials and thicknesses for the second dielectric layer may be useful.

In one embodiment, the device includes an alignment mark opening 273. The alignment mark opening may have a width of about 1 um. Providing other widths may also be useful. The alignment mark opening extends through the second dielectric layer 260 and dielectric liner 264. A barrier liner 275 lines the sides and bottom of the alignment mark opening. The barrier layer lines the alignment mark opening without filling it. A conductive material 277 fills the alignment mark opening, forming the alignment mark 278. As illustrated, a top surface of the conductive material filling the alignment mark opening is recessed from a top surface 262 of the second dielectric layer 260, forming the alignment mark. For example, the topography of the recessed conductive material in the second dielectric layer forms the alignment mark. The recessed conductive material provides a step height between the top surface of the alignment mark and the top surface of the second dielectric layer. The step height may be, for example, about 20 nm to 30 nm. Other suitable step heights may also be useful, depending on the design requirements of a technology node. The recessed alignment mark facilitates forming subsequent MTJ element patterns. The alignment mark, for example, is formed by the conductive material, such as Cu and material of the barrier liner (or barrier material) such as Ta or TaN. Other suitable types of conductive material and barrier material may also be useful. In the case where the conductive material forming the alignment mark is disposed on a metal line (e.g., metal line 252), the conductive material may also serve as a via plug. In other cases, the conductive material forming the alignment mark may be floating in the device.

In one embodiment, a first electrode layer 290 is disposed on the substrate. The first electrode layer is disposed over the second dielectric layer and alignment mark in the second dielectric layer. In one embodiment, the first electrode layer integrates or fuses with the barrier liner 275 lining the alignment mark opening. For example, the first electrode layer and the barrier liner may be formed of the same material. The first electrode layer and barrier liner, for example, may be formed of TaN. Providing the first electrode layer and the barrier liner formed of different material may also be useful.

A top surface of the first electrode layer follows the topography of the underlying second dielectric layer and the alignment mark 278 in the second dielectric layer. The top surface of the conductive material which is recessed with respect to the second dielectric layer on the substrate provides an underlying topography that facilitates formation of alignment mark 295 in the first electrode layer, which is transferred to subsequently formed layers on the first electrode layer. For example, the alignment mark may be used to pattern subsequently deposited memory stack layers of a memory cell, as described in FIG. 2a. The alignment mark is used, in one embodiment, for facilitating patterning the magnetic stack layers such that the patterned layers are aligned and coupled to one or more metal lines of the device.

In one embodiment, the first electrode layer 290 may serve as an electrode of the memory cell. The electrode, in one embodiment, may be a bottom electrode of the memory stack of the memory cell. Providing the first electrode layer for forming other elements of the device may also be useful.

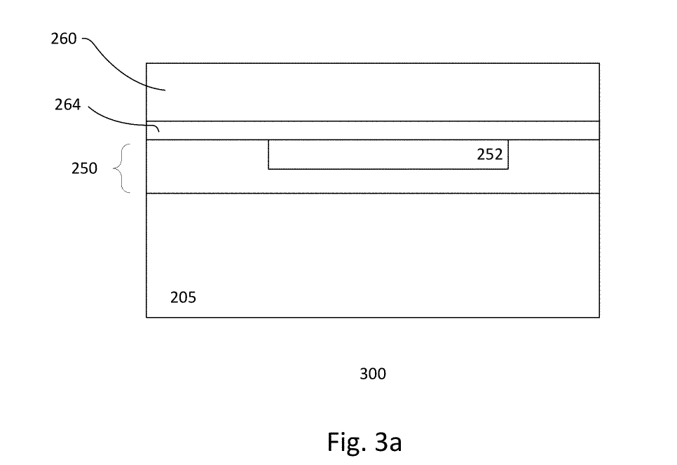

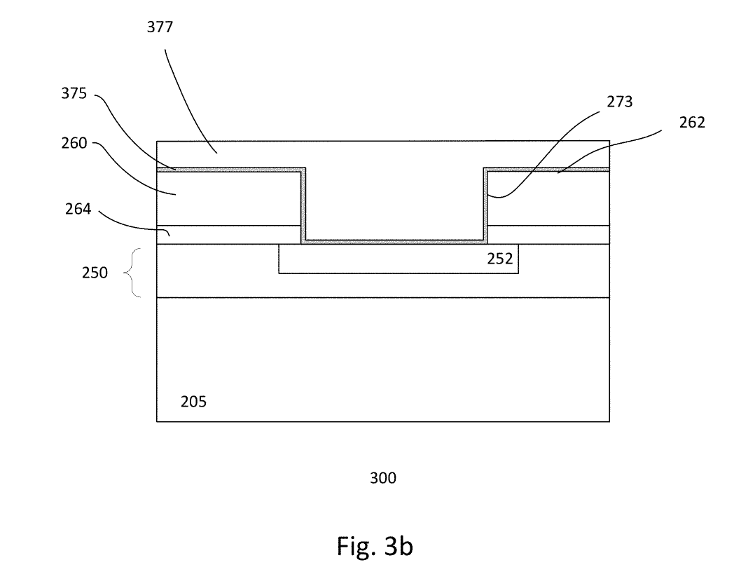

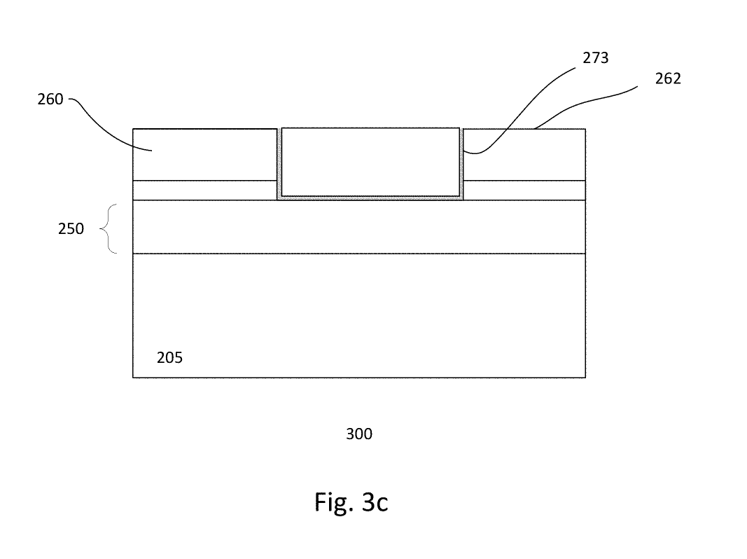

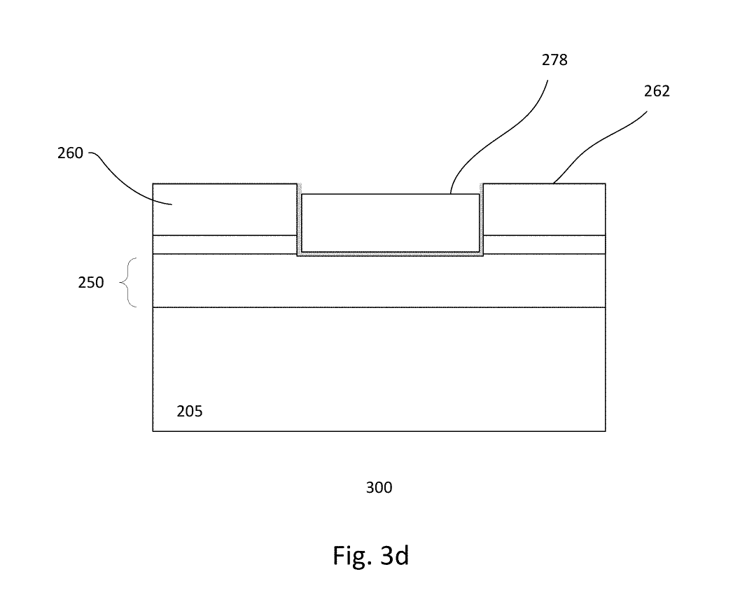

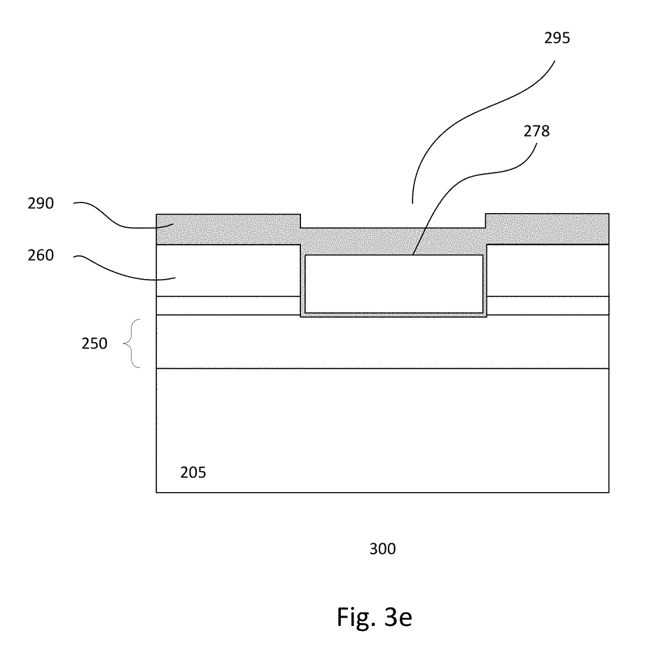

FIGS. 3a-3e show simplified cross-sectional views of an embodiment a process 300 for forming an alignment mark in a device. The device formed, for example, is similar to that shown and described in FIGS. 2a-2b. Common elements may not be described or described in detail.

For simplicity of discussion, the processing of a substrate 205 to form elements such as transistors using FEOL and processing of a first dielectric layer 250 using BEOL are not shown. The substrate 205, for example, may be a silicon substrate. Other suitable types of substrates, such as silicon germanium, germanium, gallium arsenide, or crystal-on-insulator (COI) such as silicon-on-insulator (SOI), are also useful. The substrate may be a doped substrate. The substrate can be lightly doped with p-type dopants. For example, the substrate may be silicon substrate, intrinsic or doped with other types of dopants or dopant concentrations. The substrate may be a part of a wafer which is processed in parallel to form a plurality of devices. The substrate includes first and second surfaces. The first surface may be the top surface on which an IC is mounted while the second surface is the bottom surface which is mounted onto an external component, for example, a package substrate or a circuit board.

The first dielectric layer 250 may be formed with one or more ILD layers. The ILD layers may be processed to include metal levels and contact levels. The metal level includes conductors or metal lines while the contact level includes via contacts. The uppermost ILD layer of the first dielectric layer 250, for example, may correspond to ILD level 3. It is understood that the dielectric layer may correspond to other suitable ILD level. As illustrated in FIG. 3a, the first dielectric layer may be formed with metal line 252 in the metal level of the uppermost ILD layer. Although one metal line is shown, it is understood that there could be more than one metal line formed. The metal line 252, for example, may be coupled to a memory cell which will be formed later. The metal line may be formed of a metal, such as copper, copper alloy, aluminum, tungsten or a combination thereof. Other suitable types of metal, alloys or conductive materials may also be useful.

In some embodiments, a dielectric liner 264 is formed over the first dielectric layer covering the metal line. The dielectric liner, for example, serves as an etch stop layer. The dielectric liner may be formed of a low k dielectric material. For example, the dielectric liner may be nBLOK. Other types of dielectric materials for the dielectric liner may also be useful. The dielectric liner may be formed, for example, by CVD. Other suitable techniques for forming the dielectric liner may also be useful.

The process continues to form a second dielectric layer 260 over the first dielectric layer 250. For example, the second dielectric layer 260 is formed on the dielectric liner. The second dielectric layer, for example, includes TEOS. The second dielectric layer may be formed by CVD. Any other suitable forming techniques or suitable materials and thicknesses for the second upper dielectric layer may also be useful.

Referring to FIG. 3b, the second dielectric layer 260 and the dielectric liner 264 are patterned to form one or more alignment mark openings 273. The alignment mark opening, for example, exposes a portion of the metal line 252 in the metal level below. The opening may be formed by mask and etch techniques. For example, a patterned photoresist mask may be formed over the second dielectric layer, serving as an etch mask. An etch, such as RIE, may be performed to pattern the second dielectric layer and dielectric liner using the patterned resist etch mask. In one embodiment, the etch transfers the pattern of the mask to the second dielectric layer, including the dielectric liner to expose a portion of the metal line 252 below. Other techniques for forming the alignment mark opening may also be useful. In other embodiments, the alignment mark opening may be patterned in a portion of the dielectric layer without a metal line below the alignment mark opening. The alignment mark opening extends through the second dielectric layer and the dielectric liner. The depth of the alignment mark opening, for example, is about 1000 Å. Other suitable depth may also be useful.

In one embodiment, the process continues to form a barrier liner 375 on the substrate. The barrier liner lines a top surface 262 of the second dielectric layer and the sidewalls and bottom of the alignment mark opening. As illustrated, the barrier liner covers the portion of the metal line 252 exposed by the alignment mark opening. The barrier liner, in one embodiment, includes any suitable material which is the same as the material of a first electrode layer which will be formed later on. For example, the barrier liner includes Ti, TiN, Ta, TaN material or a combination thereof. The thickness of the barrier liner is, for example, about 250 Å. Other suitable thickness for the barrier liner may also be useful. The barrier layer, for example, is formed by physical vapor deposition (PVD). Other suitable forming techniques may also be employed.

The process continues by depositing a conductive layer 377 over the second dielectric layer 260, filling the alignment mark opening. For example, the conductive layer is deposited on the barrier liner, filling the alignment mark opening. The conductive layer, for example, includes copper (Cu). The conductive layer, for example, is formed by electroplating. Other suitable conductive materials and deposition techniques may also be employed.

In one embodiment, a first planarization process such as CMP is performed on the substrate. The first planarization process removes excess conductive material on top of the second dielectric layer to form a planar top surface. The first planarization process, in one embodiment, removes portions of the barrier liner on the top surface of the second dielectric layer. The first planarization process produces a substantially planar top surface between the conductive material in the alignment mark opening and the second dielectric layer as shown in FIG. 3c.

A second planarization process such as CMP may be performed to recess the conductive material in the alignment mark opening. The second planarization process recesses the conductive material to form a step height between a top surface 278 of the conductive material and a top surface 262 of the second dielectric layer. For example, the top surface 278 of the conductive material is disposed on a different plane than the top surface 262 of the second dielectric layer. The recessed top surface of the conductive material forms the alignment mark in the second dielectric layer. The conductive material, in one embodiment, is recessed to a depth of about 200 to 300 Å from the top surface of the second dielectric layer. Other suitable depths for recessing the conductive material may also be useful as long as it is sufficiently deep to create adequate topography for forming an alignment mark in a subsequent deposited layer above it. In some embodiments, the second planarization process may be performed, for example, to recess two or more via plugs and alignment marks in the second dielectric layer in parallel, depending on the requirement of the device processing scheme.

In another embodiment, the first and second planarization processes may be combined as one step planarization process to form the alignment mark in the dielectric layer. For example, the CMP process removes excess conductive material over the second dielectric layer including a portion of conductive material in the alignment mark opening without removing the barrier liner. In other words, the conductive material in the alignment mark opening is recessed with respect to the second dielectric layer and the barrier liner remaining on the top surface of the second dielectric layer outside the alignment mark opening in the one step planarization process. The CMP process results in a planar surface of the barrier liner on the top surface of the second dielectric layer and a planar surface of the recessed conductive material in the alignment mark opening. The barrier material (e.g., Ta/TaN) outside the alignment mark opening may then be removed after the selective one step planarization process of the conductive material. The barrier liner on the top surface of the second dielectric layer may be removed, for example, by CMP.

As shown in FIG. 3e, a first electrode layer 290 is deposited on the substrate. The first electrode layer is conformally deposited over the second dielectric layer and the alignment mark. For example, the first electrode layer is conformally deposited over the planarized second dielectric layer and the recessed conductive material. The first electrode layer integrates or fuses with a portion of the barrier liner lining the alignment mark opening. The first electrode layer, for example, includes the same material as the barrier liner. For example, the first electrode layer includes Ti, TiN, Ta, TaN material or a combination thereof. The thickness of the first electrode layer, for example, is about 500 Å. Other suitable thickness may also be useful. As shown, the first electrode layer tracks the profile of the underlying second dielectric layer and recessed alignment mark, further forming an alignment mark 295 in the first electrode layer.

The process continues to form an IC of the device. For example, the process forms a memory cell of the device. In one embodiment, the first electrode layer serves as a bottom electrode of the memory cell. The topography of the alignment mark 295 in the first electrode layer is transferred to the top surface of subsequent layers formed on the first electrode layer such as other dielectric layers. For example, oxide or low k layers may be formed on the first electrode layer. The oxide or low k layers follow the topography of the underlying alignment mark. This creates adequate topography feature which is visible from the top surface of the substrate. Thus, the topography may be used as the alignment mark during patterning to define the memory element later. The process forms various layers of a memory stack over the first electrode layer as described in FIG. 2a. For example, the memory stack may be formed on a flat portion of the underlying first electrode layer. The various layers of the memory stack may be sequentially formed over the first electrode layer.

In one embodiment, the process further forms a second electrode layer and a hard mask layer over the various layers of the memory stack. The second electrode layer, for example, includes the same material as the first electrode layer. For example, the second electrode layer includes Ti, TiN, Ta, TaN material or a combination thereof. The hard mask layer, for example, includes TEOS hard mask. These layers, for example, may be formed over the memory stack by CVD. Other suitable types of materials and forming techniques may be used for the second electrode and hard mask layers. The first and second electrode layers and various layers of the memory stack are then patterned. Patterning the layers may be achieved with mask and etch techniques. A soft mask layer, such as a photoresist layer, is formed on the hard mask layer. The soft mask is patterned to form a pattern which is used to define the pattern of the second electrode, layers of the memory stack and the first electrode. To form the pattern in the mask layer, it may be selectively exposed with an exposure source using a reticle. In one embodiment, the reticle used to expose the resist layer is aligned using the alignment mark 295 in the first electrode layer, which is visible as topography on the subsequently formed layers. The pattern of the reticle is transferred to the resist layer after exposure by a development process.

An etch process is performed to remove the exposed hard mask layer, first and second electrode layers and various layers of the memory stack not protected by the patterned mask. The etch, for example, is an anisotropic etch, such as a RIE. Other suitable techniques for patterning the memory stack and first and second electrode layers may also be useful. The etch process stops when it reaches the top surface of the second dielectric layer 260. For example, the etch is selective to the material of the second dielectric layer 260. The soft mask may be removed thereafter.

The process may continue to form additional upper dielectric layers with interconnects therein and to complete formation of the IC. The process, for example, may continue to form passivation layer and pad interconnects or bonding pads. Further processing may include final passivation, dicing, assembly and packaging. Other processes are also useful.

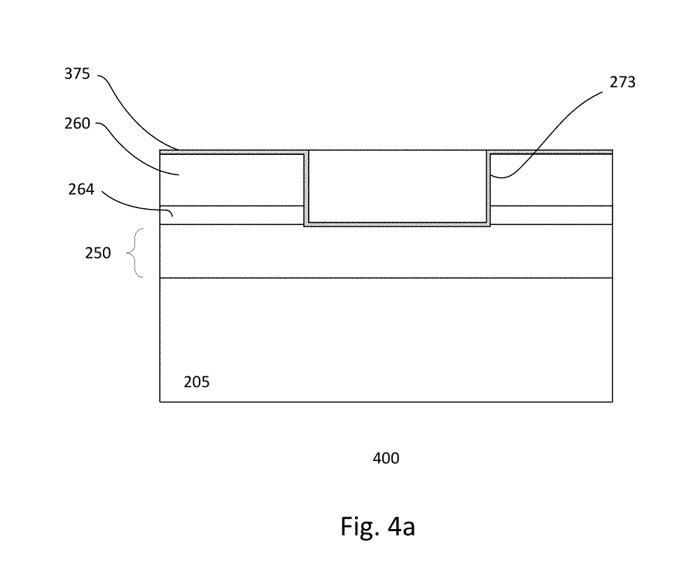

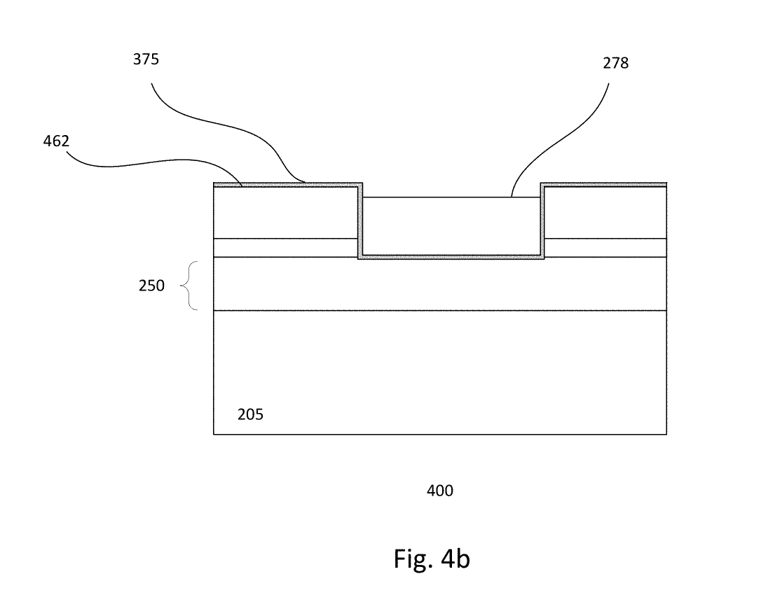

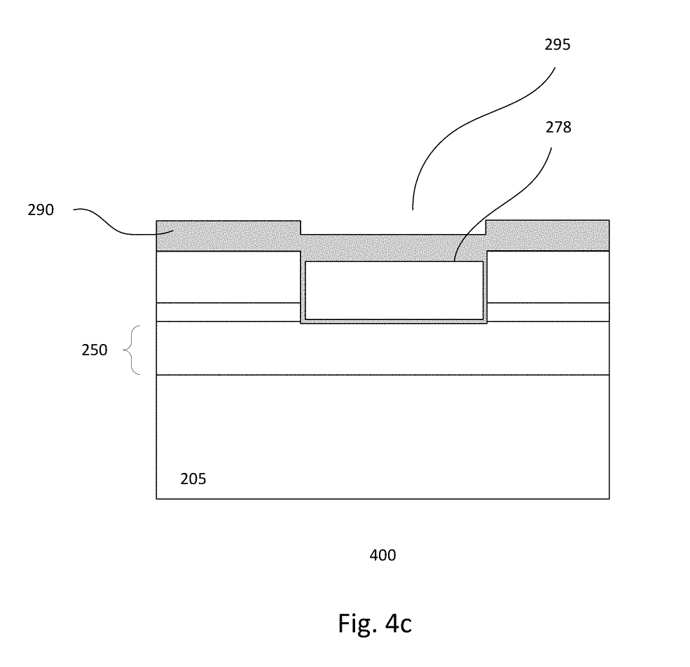

FIGS. 4a-4c show another embodiment of a process 400 for forming an alignment mark in a device. The process 400 is similar to that described in FIGS. 3a-3e and the device formed, for example, is similar to that shown and described in FIGS. 2a-2b. Common elements may not be described or described in detail.

Referring to FIG. 4a, a substrate 205 is provided. The substrate is at the stage of processing as described in FIG. 3b. For example, a dielectric liner 264 and second dielectric layer 260 are formed over the first dielectric layer 250. An alignment mark opening 273 is formed through the second dielectric layer and the dielectric liner. A barrier liner 375 is formed over the substrate. The barrier liner lines the top surface of the second dielectric layer and sidewalls and bottom of the alignment mark opening. Similarly, a conductive layer is deposited over substrate. The conductive material of the conductive layer fills the alignment mark opening. For example, the conductive layer is deposited on the barrier layer, filling the via opening. The conductive layer, for example, may be formed by CVD. The conductive layer, for example, includes Cu. Other suitable conductive materials and deposition techniques may also be employed.

The process continues by performing a first planarization process such as CMP on the substrate. In one embodiment, the first planarization process removes excess conductive material on top of the second dielectric layer 260 and stops on the barrier liner on the top surface of the second dielectric layer to provide a substantially planar top surface between the conductive material in the alignment mark opening and the barrier liner. For example, the first planarization process leaves the barrier liner on the top surface of the second dielectric layer remaining.

In one embodiment, a second planarization process such as CMP may be performed to recess the conductive material in the alignment mark opening as shown in FIG. 4b. The second planarization process produces a recessed top surface 278 of the conductive material in the alignment mark opening, forming an alignment mark in the second dielectric layer. The barrier liner remains on the second dielectric layer. The first and second planarization processes may also be combined as one step planarization process to achieve the same topology performance. The conductive material in the alignment mark opening, in one embodiment, is recessed to a depth below a top surface of the second dielectric layer. For example, a top surface 278 of the conductive material in the alignment mark opening is disposed on a different plane than a top surface 462 of the second dielectric layer. Recessing the conductive material in the alignment mark opening to a depth below the top surface of the second dielectric layer produces a step height. For example, the top surface 278 of the conductive material in the alignment mark opening serving as the alignment mark has a step height of about 20 to 30 nm from the top surface of the second dielectric layer. Other suitable depth for recessing the conductive material may also be useful as long as it is sufficiently deep to create adequate topography for forming an alignment mark in a subsequently deposited layer above it. In some embodiments, the second planarization process may be performed, for example, to recess two or more alignment mark and via plugs in the second dielectric layer, depending on device processing scheme requirement.

As shown in FIG. 4c, a first electrode layer 290 is deposited over the substrate. The first electrode layer is conformally deposited over the barrier liner and alignment mark in the second dielectric layer. For example, the first electrode layer is conformally deposited over the planarized portion of the barrier liner on the second dielectric layer and the recessed alignment mark as well as one or more via plugs formed in the device. The first electrode layer tracks the profile of the underlying layer on which it is deposited. As shown, the first electrode layer tracks the profile of the recessed alignment mark 278 in the second dielectric layer, forming an alignment mark 295 in the first electrode layer. The first electrode layer integrates or fuses with portions of the barrier liner that lines the top surface of the second dielectric layer and the alignment mark opening.

Material and technique for forming the first electrode layer are the same as that described in FIG. 3e. The first electrode layer, for example, includes the same material as the barrier liner. Since the first electrode layer and the barrier liner include the same material, the first electrode layer is provided with suitable thickness such that the first electrode layer and the barrier liner on the top surface of the second dielectric layer in combination provide for the desired thickness, serving as a first electrode of a memory cell. The first electrode layer may be deposited such that the combined thickness of the first electrode layer and the barrier liner, for example, is about 500 Å. Other suitable thickness may also be useful.

The process continues to form an IC of the device using the topography of the alignment mark. For example, the process 400 continues to form various layers of the memory cell as described with respect to FIG. 3e onwards. The process continues until a device similar to that shown in FIG. 2a is formed. For example, the process forms a memory cell of the device. Various layers of a memory stack may be formed over the first electrode layer using the alignment mark for alignment.

The process may continue to form additional upper dielectric layers with interconnects therein and to complete formation of the IC. The process, for example, may continue to form passivation layer and pad interconnects or bonding pads. Further processing may include final passivation, dicing, assembly and packaging. Other processes are also useful.

The process 300 or 400 as illustrated forms an alignment mark which is transferred to top surfaces of subsequently formed layers, forming a topography feature which is used to facilitate patterning of layers in a device. For example, the topography feature which is visible from the top surface of the wafer serves as an alignment mark for facilitating patterning of the memory layers to ensure that the patterned memory stack is aligned and coupled to the underlying via plug and metal line. Additionally, forming the alignment mark in the dielectric layer using CMP and transferring the topography to subsequently formed layers obviates the need to for additional processing steps to form alignment mark such as additional deposition layers, mask and patterning process specifically for forming an alignment mark. This advantageously reduces manufacturing costs.

The present disclosure may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A method of forming a device comprising:
providing a substrate;
forming a dielectric layer over the substrate;
forming an alignment mark opening in the dielectric layer which extends through the dielectric layer;
forming a barrier liner over the dielectric layer, wherein the barrier liner lines a top surface of the dielectric layer and the alignment mark opening;
depositing a conductive layer over the barrier liner; and
performing a planarization process, wherein the planarization process recesses a top surface of the conductive material in the alignment mark opening with respect to the dielectric layer, forming an alignment mark of the device.

2. The method of claim 1 wherein the planarization process comprises chemical mechanical polishing.

3. The method of claim 2 wherein the planarization process comprises:
a first planarization process that forms a substantially planar top surface between the conductive material in the alignment mark opening and the dielectric layer; and
a second planarization process that recesses the top surface of the conductive material in the alignment mark opening with respect to the dielectric layer.

4. The method of claim 2 wherein the planarization process removes excess conductive material on the dielectric layer on the top surface of the second dielectric layer and recesses a top surface of the conductive material in the alignment mark opening in a one-step planarization process, without removing the barrier liner on the top surface of the dielectric layer.

5. The method of claim 4 further comprising performing a second planarization process to remove the barrier liner on the top surface of the dielectric layer.

6. The method of claim 2 wherein the planarization process comprises:
a first planarization process that forms a substantially planar top surface between the conductive material in the alignment mark opening and the barrier liner; and
a second planarization process that recesses the top surface of the conductive material in the alignment mark opening with respect to the dielectric layer, wherein the barrier liner remains on the dielectric layer.

7. The method of claim 1 further comprising forming a first electrode layer over the dielectric layer, wherein a topography of the dielectric layer and the alignment mark in the dielectric layer is transferred to the first electrode layer.

8. The method of claim 7 wherein the first electrode layer and the barrier liner comprise the same material.

9. The method of claim 8 wherein the first electrode layer and the barrier liner comprise Ti, TiN, Ta, TaN, or a combination thereof.

10. The method of claim 7 comprising:
forming various layers of a memory stack over the first electrode layer, wherein the topography of the alignment mark in the dielectric layer is transferred to surfaces of the various layers of the memory stack; and
patterning the various layers of the memory stack to form a memory element using the alignment mark.

11. The method of claim 1 wherein the top surface of the conductive material in the alignment mark opening is recessed with respect to the top surface of the dielectric layer to form a step height of about 20 nm to 30 nm.

12. The method of claim 1 wherein the alignment mark is formed above a metal line in the device.

13. The method of claim 1 wherein the dielectric layer comprises one or more via plugs.

14. The method of claim 1 comprising forming a dielectric liner over the substrate and forming the dielectric layer over the dielectric liner, wherein the alignment mark opening extends through the dielectric liner.

15. A method of forming a device comprising:
providing a substrate;
forming a dielectric layer over the substrate;
forming an alignment mark opening in the dielectric layer which extends through the dielectric layer;
depositing a conductive layer over the dielectric layer;
performing a planarization process, wherein the planarization process removes excess conductive material on the dielectric layer and recesses a top surface of the conductive material in the alignment mark opening with respect to the dielectric layer, forming an alignment mark of the device; and
forming a first electrode layer over the dielectric layer, wherein a topography of the dielectric layer and the alignment mark in the dielectric layer is transferred to the first electrode layer.

16. The method of claim 15 comprising forming a barrier liner over the dielectric layer, wherein the barrier liner lines a top surface of the dielectric layer and the alignment mark opening.

17. The method of claim 16 wherein the planarization process comprises:
a first planarization process that forms a substantially planar top surface between the conductive material in the alignment mark opening and the barrier liner; and
a second planarization process that recesses the top surface of the conductive material in the alignment mark opening with respect to the dielectric layer, wherein the barrier liner remains on the dielectric layer.

18. The method of claim 15 wherein the planarization process comprises:
a first planarization process that forms a substantially planar top surface between the conductive material in the alignment mark opening and the dielectric layer; and
a second planarization process that recesses the top surface of the conductive material in the alignment mark opening with respect to the dielectric layer.

19. A wafer comprising:
a wafer substrate;
a dielectric layer disposed over the substrate;
an alignment mark disposed in the dielectric layer, wherein the alignment mark is recessed with a step height from a top surface of the dielectric layer.

20. The wafer of claim 19 wherein the alignment mark is formed of a conductive material and a barrier material.
